(19) United States
(12) Patent Application Publication
(10) Pub. No.: US 2025/0130257 A1
(43) Pub. Date: Apr. 24, 2025

(54) CURRENT SENSOR

(71) Applicant: Asahi Kasei Microdevices Corporation, Tokyo (JP)

(72) Inventor: Ryuji NOBIRA, Tokyo (JP)

(21) Appl. No.: 18/921,027

(22) Filed: Oct. 21, 2024

(30) Foreign Application Priority Data
Oct. 23, 2023 (JP) 2023-181912
Sep. 30, 2024 (JP) 2024-169809

(51) Int. Cl. G01R 19/15; G01R 15/00; G01R 19/165; G01R 33/07; G01R 33/09; H03G 3/20

(52) U.S. Cl. CPC G01R 19/15; G01R 15/002; G01R 19/165; G01R 33/07; G01R 33/09; H03G 3/20

(57) ABSTRACT

A current sensor may include a detection unit which outputs a detection signal corresponding to a magnetic field generated around a conductor by a flow of a measurement current therein; an amplification circuit, including a first input terminal, a second input terminal, and an output terminal, which amplifies the detection signal input via the first input terminal and outputs an output signal via the output terminal; and a control circuit which is capable of inputting an offset signal to the first input terminal. The amplification circuit may be configured to be capable of switching at least a first amplification factor and a second amplification factor, and the control circuit may turn off the input of the offset signal to the first input terminal during a period in which the first amplification factor is set, and turn on it during a period in which the second amplification factor is set.

The contents of the following patent application(s) are incorporated herein by reference:
NO. 2023-181912 filed in JP on Oct. 23, 2023
NO. 2024-169809 filed in JP on Sep. 30, 2024.

### BACKGROUND

### 1. Technical Field

The present invention relates to a current sensor.

### 2. Related Art

Patent document 1 discloses a current sensor having gain that cancels out change in detection gain in at least part of a gain variation band. Patent document 2 discloses alternately switching between small and large input ranges by a gain switching circuit while reading in digital values at oversampling frequencies higher than the conventional sampling frequency for A/D conversion. Patent document 3 discloses an amplifier capable of automatically switching gain in response to an input voltage. Patent document 4 discloses that an amplification factor of an operational amplifier can be varied based on an output voltage of a current detector.

### PRIOR ART DOCUMENTS

### Patent Documents

Patent Document 1: Japanese Patent Application Publication No. 2020-038196
Patent Document 2: Japanese Patent Application Publication No. 2019-152471
Patent Document 3: Japanese Patent Application Publication No. 2004-336300
Patent Document 4: Japanese Patent Application Publication No. 2010-197065

### BRIEF DESCRIPTION OF THE DRAWINGS

FIG. 1 illustrates an example of a circuit configuration of a current sensor including a correction unit.

FIG. 2 illustrates an example of a circuit configuration of a current sensor according to a first embodiment.

FIG. 3 illustrates an example of a circuit configuration of an amplification unit when an inverting amplification circuit is used.

FIG. 4 illustrates a variant of the circuit configuration of the current sensor according to the first embodiment.

FIG. 5A illustrates an example of output characteristics of an output signal VOUT with respect to a detection signal VIN.

FIG. 5B illustrates an example of output characteristics of the output signal VOUT with respect to the detection signal VIN.

FIG. 6A is a block diagram of the operational amplifier of FIG. 3 when a switch SW2a, SW2b, and SW2c are in an OFF state.

FIG. 6B is a block diagram of the operational amplifier of FIG. 3 when the switch SW2a, SW2b, and SW2c are in an ON state.

FIG. 7 illustrates an example of a Bode plot illustrating a relationship between F0 and a feedback factor β when the operational amplifier of FIG. 3 has a finite amplification factor A0 and characteristics of a first order LPF.

FIG. 8 illustrates an example of a circuit configuration of a current sensor according to a second embodiment.

FIG. 9 illustrates an example of a circuit configuration of an amplification unit when an inverting amplification circuit is used.

FIG. 10 illustrates a variant of the circuit configuration of the amplification unit when the inverting amplification circuit is used.

### DESCRIPTION OF EXEMPLARY EMBODIMENTS

Hereinafter, embodiments of the present invention will be described. However, the following embodiments are not for limiting the invention according to the claims. In addition, not all of the combinations of features described in the embodiments are essential to the solving means of the invention.

In a current sensor that uses a magnetic sensor to detect a magnetic field generated around a conductor when a current flows, it is possible to expand a measurable current range by using a correction unit configured by a non-volatile memory or a register to correct offset or adjust gain of an amplification unit that amplifies a signal output by the magnetic sensor.

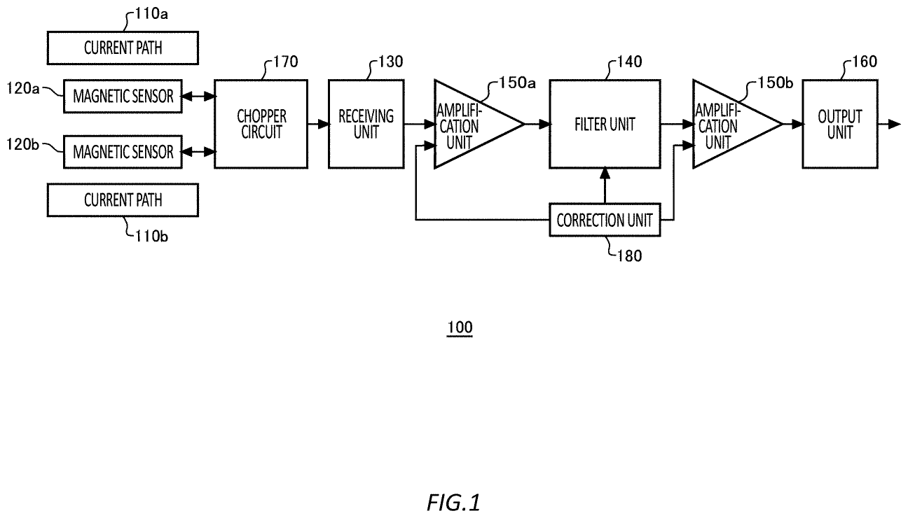

FIG. 1 illustrates an example of a circuit configuration of a current sensor 100 including a correction unit as described above. The current sensor 100 has a configuration in which a measurement current flowing through current paths 110a, 110b is detected by two pairs of magnetic sensors 120a, 120b, thereby reducing an effect of an offset magnetic field caused by external disturbance. A chopper circuit 170 is coupled between the magnetic sensors 120a, 120b and a receiving unit 130, and chops a signal output by the magnetic sensors 120a, 120b. The chopper circuit 170 calculates a difference between signals in a 0 degree direction and a 90 degree direction output from the magnetic sensors 120a, 120b, removes the offset voltage and the like, and outputs the processed signal to the receiving unit 130.

The receiving unit 130 is coupled to an amplification unit 150a and is a wiring or terminal for coupling the signal processed by the chopper circuit 170 to the amplification unit 150a. The amplification unit 150a amplifies the signal with a predetermined gain and outputs it to the filter unit 140. The filter unit 140 is coupled to an amplification unit 150b, filters the signal received by the receiving unit 130 to decrease its amplitude within a predetermined frequency range, and outputs the filtered signal.

The amplification unit 150b is coupled to an output unit 160, amplifies the amplitude of the signal with a predetermined gain, and outputs the amplified signal. The output unit 160 outputs the output signal representing the measurement current in response to the filtered signal received from the amplification unit 150b.

A correction unit 180 is coupled to the amplification units 150a, 150b and the filter unit 140, corrects the signal, and adjusts the current value signal output from the output unit 160 to a desired unique value.

In such a current sensor 100, initial configuration is required in the correction unit 180 each time gain setting is changed, and the measurable current range cannot be expanded unless the gain setting is changed. In addition, even when gain of the amplification unit is switched depending on magnitude of amplitude of a signal output from the magnetic sensor, amplitude of the signal output from the amplification unit may vary with switching of gain.

Therefore, there is a demand for a current sensor that can expand the measurable current range while suppressing variations in amplitude of the signal output from the amplification unit that occur with switching of gain.

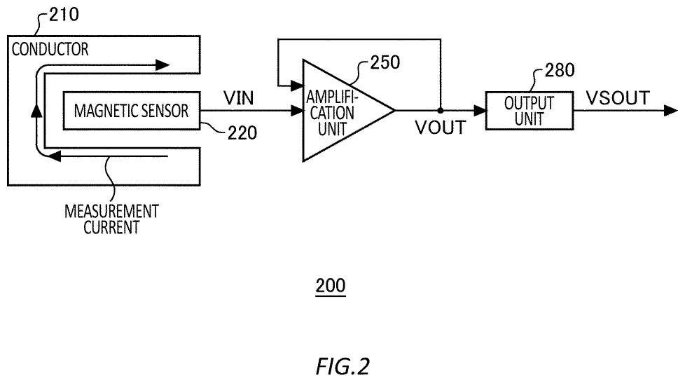

FIG. 2 illustrates an example of a circuit configuration of a current sensor 200 according to a first embodiment. The current sensor 200 detects a measurement current flowing through a conductor 210 that is a current path. The current sensor 200 includes a magnetic sensor 220, an amplification unit 250, and an output unit 280. The current sensor 200 may be a semiconductor package in which at least one configuration of the current sensor 200 is disposed on a substrate and is covered with a package formed of an insulating material such as molded resin, ceramic, or the like.

The current sensor 200 processes a signal output from the magnetic sensor 220 in response to the measurement current flowing through the conductor 210 and outputs an output signal representing a current amount, rise, fall, or the like of the measurement current.

The conductor 210 may be a conductor such as a metal provided on a substrate built into the semiconductor package. The conductor 210 may be a part of a lead frame configuring a pair of terminals through which the measurement current flows. In FIG. 2, the conductor 210 is in a plan view, and the measurement current flows in right-hand rotation around the magnetic sensor 220. A cross-sectional shape of the conductor 210 across the direction in which the current flows may be a rectangle, square, trapezoid, polygon, circle, ellipse, or the like, or may be a combination of these. When the measurement current flows through the conductor 210, a magnetic field of right-hand rotation (clockwise) is generated around the conductor 210 with respect to the direction in which the measurement current flows. In this way, the magnetic field is applied to the magnetic sensor 220 in a substantially downward direction.

The magnetic sensor 220 is disposed near the conductor 210. The magnetic sensor 220 is an example of a magnetoelectric conversion element. The magnetoelectric conversion element includes at least one of a Hall element, a magneto-resistance element (MR), a giant magneto-resistance element (GMR), a tunneling magneto-resistance element (TMR), a magnetic impedance element (MI element), an inductance sensor, or the like. The magnetic sensor 220 is an example of a detection unit that outputs a detection signal corresponding to a magnetic field generated around the conductor 210 by a flow of a measurement current therein.

The magnetic sensor 220 may be built into the same package as the conductor 210. The magnetic sensor 220 detects the magnetic field generated by the measurement current flowing through the conductor 210, and outputs, to the amplification unit 250, the detection signal having a current value or a voltage value corresponding to the magnetic field.

The amplification unit 250 is coupled to the output unit 280. The amplification unit 250 may include an inverting amplification circuit or a non-inverting amplification circuit using an operational amplifier. The amplification unit 250 may amplify the amplitude of the signal by a predetermined gain and output it. The amplification unit 250 feeds back an output signal VOUT, judges the output result based on a predetermined threshold, and controls gain so that it is smaller than a predetermined gain. In addition, the amplification unit 250 may control the gain based on a threshold selected from a plurality of thresholds.

The output unit 280 outputs a sensor output signal VSOUT that represents magnitude of the measurement current depending on the signal received from the amplification unit 250. The output unit 280 may be an operational amplifier or a comparator. The amplification unit 250 may perform control of the gain of the amplification unit 250 by feeding back the sensor output signal VSOUT.

The current sensor 200 according to the first embodiment includes one magnetoelectric conversion element such as a Hall element or the like as the magnetic sensor 220. However, a number of the magnetic sensors 220 included in the current sensor 200 is not limited to one. The current sensor 200 may include a plurality of the magnetic sensors 220. For example, a pair of the magnetic sensors 220 may be disposed facing each other across the conductor 210 in a plan view. The current sensor 200 may amplify, in the amplification unit 250, a signal after canceling an effect of an externally generated magnetic field based on the plurality of magnetoelectric conversion elements and outputs of the plurality of magnetoelectric conversion elements. The current sensor 200 may include the chopper circuit 170, the receiving unit 130, and the filter unit 140 illustrated in FIG. 1.

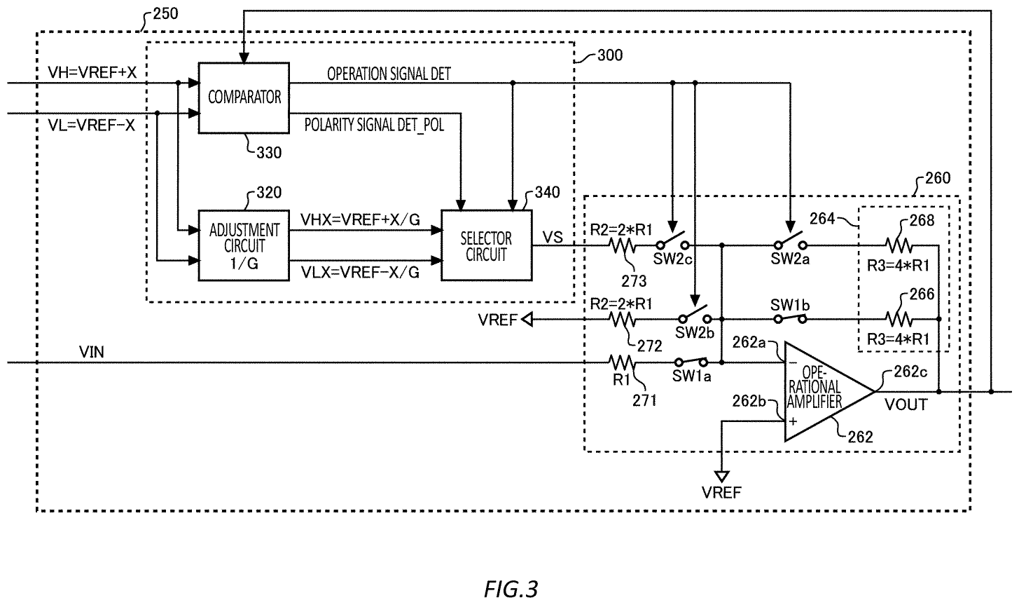

FIG. 3 illustrates an example of a circuit configuration of the amplification unit 250 when an inverting amplification circuit is used. The amplification unit 250 includes an amplification circuit 260 and a control circuit 300. The amplification unit 250 includes an operational amplifier 262 and a feedback resistance circuit 264.

The operational amplifier 262 includes an inverting input terminal 262a, a non-inverting input terminal 262b, and an output terminal 262c. The inverting input terminal 262a is an example of a first input terminal. The non-inverting input terminal 262b is an example of a second input terminal. The operational amplifier 262 amplifies a detection signal VIN from the magnetic sensor 220 input via the inverting input terminal 262a and outputs the output signal VOUT via the output terminal 262c.

The control circuit 300 sets an amplification factor of the amplification circuit 260 to a first amplification factor when an amplitude of the output signal VOUT falls within a predetermined amplitude range W, and sets the amplification factor of the amplification circuit 260 to a second amplification factor lower than the first amplification factor when the amplitude of the output signal VOUT does not fall within the predetermined amplitude range W. In this way, the current range that is measurable by the current sensor 200 can be expanded. However, the amplitude of the output signal VOUT varies at a timing when the amplification factor of the amplification circuit 260 switches between the first amplification factor and the second amplification factor. When the amplitude of the output signal VOUT varies, variation in measurement accuracy of the current sensor 200 occurs.

Therefore, the control circuit 300 adds, to the detection signal VIN while the amplification factor of the amplification circuit 260 is set to the second amplification factor, an offset signal VS that suppresses change in the amplitude of the output signal VOUT that occurs in response to the switching of the amplification factor of the amplification circuit 260 between the first amplification factor and the second amplification factor, and inputs the result to the inverting input terminal 262a.

The feedback resistance circuit 264 is coupled between the output terminal 262c and the inverting input terminal 262a, set to a first resistance value in the case of the first amplification factor, and set to a second resistance value lower than the first resistance value in the case of the second amplification factor. The control circuit 300 sets the resistance value of the feedback resistance circuit 264 to the first resistance value when the amplitude of the output signal VOUT falls within the predetermined amplitude range W, and sets the resistance value of the feedback resistance circuit 264 to the second resistance value when the amplitude of the output signal VOUT does not fall within the predetermined amplitude range W.

The feedback resistance circuit 264 includes a resistance element 266 and a resistance element 268. The resistance element 266 is an example of a first resistance element that is coupled between the output terminal 262c and the inverting input terminal 262a. The resistance element 268 is an example of a second resistance element that is coupled in parallel with the resistance element 266 between the output terminal 262c and the inverting input terminal 262a. A resistance value R2 of a resistance element 272 and a resistance element 273 may be double a resistance value R1 of a resistance element 271 (R2=2× R1). A resistance value R3 of the resistance element 266 and the resistance element 268 may be four times the resistance value R1 of the resistance element 271 (R3=4× R1).

When the amplitude of the output signal VOUT falls within the predetermined amplitude range W, the control circuit 300 controls the feedback resistance circuit 264 so that the resistance element 266 is electrically coupled between the output terminal 262c and the inverting input terminal 262a, and the resistance element 268 is not electrically coupled between the output terminal 262c and the inverting input terminal 262a. When the amplitude of the output signal VOUT does not fall within the predetermined amplitude range W, the control circuit 300 controls the feedback resistance circuit 264 so that the resistance element 266 and the resistance element 268 are electrically coupled between the output terminal 262c and the inverting input terminal 262a.

Further, when the amplitude of the output signal VOUT exceeds an upper limit value VH of the predetermined amplitude range W, the control circuit 300 adds a first offset signal VHX of a first voltage to the detection signal VIN as the offset signal VS. When the amplitude of the output signal VOUT falls below a lower limit value VL of the predetermined amplitude range W, the control circuit 300 adds a second offset signal VLX of a second voltage lower than the first voltage to the detection signal VIN as the offset signal VS.

Here, when a configuration is made in which the offset signal VS is added to the detection signal VIN, impedance seen from the inverting input terminal 262a of the operational amplifier 262 changes. As an effect, a feedback factor β of the operational amplifier 262 changes. When the feedback factor β of the operational amplifier 262 changes, frequency response of the operational amplifier 262 changes.

Therefore, the amplification circuit 260 includes a resistance element 272 as an impedance element that functions for suppressing the change in the feedback factor of the amplification circuit 260 (operational amplifier 262) that occurs by adding the offset signal VS to the detection signal VIN, and of which one end is coupled to the inverting input terminal 262a. A reference voltage VREF that is applied to the inverting input terminal 262a may be applied to another end of the resistance element 272.

The amplification circuit 260 further includes the resistance element 271 having one end to which the detection signal VIN is input and another end coupled to the inverting input terminal 262a, and the resistance element 273 having one end to which the offset signal VS is input and another end coupled to the non-inverting input terminal 262b. The resistance element 271 is an example of a third resistance element, the resistance element 272 is an example of a fourth resistance element, and the resistance element 273 is an example of a fifth resistance element.

The amplification circuit 260 further includes a switch SW2a that switches whether the resistance element 268 is electrically coupled between the output terminal 262c and the inverting input terminal 262a. The amplification circuit 260 includes a switch SW2b that switches whether the resistance element 272 is electrically coupled to the inverting input terminal 262a. The amplification circuit 260 includes a switch SW2c that switches whether the resistance element 273 is electrically coupled to the inverting input terminal 262a.

The amplification circuit 260 may further include a switch SW1a that switches whether the resistance element 271 is electrically coupled to the inverting input terminal 262a, and a switch SW1b that switches whether the resistance element 266 is electrically coupled between the output terminal 262c and the inverting input terminal 262a.

The control circuit 300 includes an adjustment circuit 320, a comparator 330, and a selector circuit 340 to switch the amplification factor of the amplification circuit 260 by performing control of each switch SW and control of input of the offset signal VS.

The comparator 330 is a circuit that performs threshold judgment. When the amplitude of the output signal VOUT does not fall within the predetermined amplitude range W, the comparator 330 operates the switch SW2a, the switch SW2b, and the switch SW2c, electrically couples the resistance element 268 between the output terminal 262c and the inverting input terminal 262a, electrically couples the resistance element 272 to the inverting input terminal 262a, and outputs an operation signal DET and a polarity signal DET_POL. The operation signal DET represents a command to electrically couple the resistance element 273 to the inverting input terminal 262a. The polarity signal DET_POL represents whether the amplitude of the output signal VOUT exceeds the upper limit value VH of the predetermined amplitude range W, or falls below the lower limit value VL of the predetermined amplitude range W. The comparator 330 outputs the operation signal DET and the polarity signal DET_POL by comparing a first threshold signal HV of a third voltage and a second threshold signal HL of a fourth voltage with the output signal VOUT. The first threshold signal HV represents the upper limit value VH of the predetermined amplitude range W obtained by adding a threshold voltage X to the reference voltage VREF (VH=VREF+X). The second threshold signal HL represents the lower limit value VL of the predetermined amplitude range W obtained by subtracting the threshold voltage X from the reference voltage VREF (VL=VREF−X).

When the amplitude of the output signal VOUT exceeds the upper limit value VH of the predetermined amplitude range W based on the operation signal DET and the polarity signal DET_POL, the selector circuit 340 inputs the first offset signal VHX of the first voltage as the offset signal VS to the one end of the resistance element 273. When the amplitude of the output signal VOUT falls below the lower limit value VL of the predetermined amplitude range W, the selector circuit 340 inputs the second offset signal VLX of the second voltage lower than the first voltage as the offset signal VS to the one end of the resistance element 273.

The adjustment circuit 320 adjusts the offset signal VS to be added to the detection signal VIN. The adjustment circuit 320 inputs, to the selector circuit 340, the first offset signal VHX of a first voltage VHX obtained by adding an adjustment voltage X/G based on the threshold voltage X to the reference voltage VREF (VHX=VREF+X/G), and the second offset signal VLX of a second voltage VLX obtained by subtracting the adjustment voltage X/G from the reference voltage VREF (VLX=VREF−X/G). The selector circuit 340 determines whether the amplitude of the output signal VOUT exceeds the upper limit value VH or falls below the lower limit value VL of the predetermined amplitude range W based on the operation signal DET and the polarity signal DET_POL, and depending on the determination result, outputs one of the first offset signal VHX and the second offset signal VLX input from the adjustment circuit 320.

According to the configuration above, the current sensor 200 can expand the measurable current range while suppressing variations in the amplitude of the output signal VOUT output from the amplification unit 250 that occur with switching of the gain.

The magnetic sensor 220 detects the magnetic field generated by the measurement current flowing through the conductor 210, and inputs, to the amplification unit 250, a signal having the current value or the voltage value corresponding to the magnetic field as the detection signal VIN. The detection signal VIN is input to the inverting input terminal 262a that is an input terminal of a negative feedback circuit configured by the operational amplifier 262, via the resistance element 271 and the switch SW1a. The output terminal 262c of the operational amplifier 262 is coupled to the inverting input terminal 262a via the resistance element 266 and the switch SW1b.

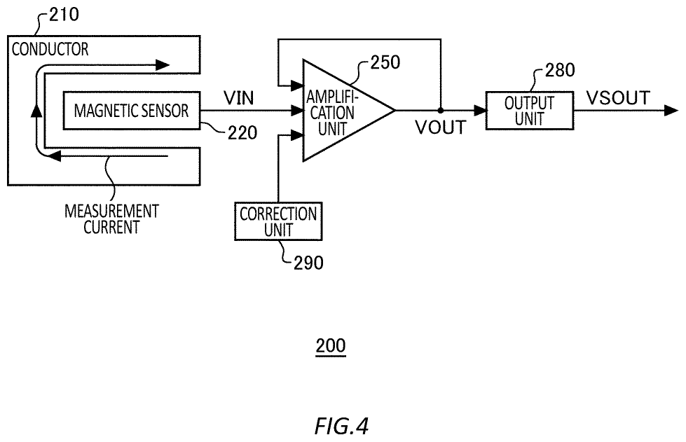

In the current sensor 200 according to the first embodiment, the switch SW1a and the switch SW1b are configured to always be in the ON state. However, the current sensor 200 may include a plurality of combinations of the switch SW1a, the switch SW1b, the resistance element 271, and the resistance element 266. In this case, the current sensor 200 may include a correction unit 290 similar to the correction unit 180 of FIG. 1, as illustrated in FIG. 4. The control circuit 300 may have a function that can control a plurality of switches SW1 from the correction unit 290 and adjust a reference gain (R3/R1).

The output terminal 262c of the operational amplifier 262 is further coupled to the inverting input terminal 262a via the resistance element 268 and the switch SW2a. An initial configuration of the switch SW2a is in the OFF state. The initial configurations of the switch SW2b and the switch SW2c are also in the OFF state.

The reference voltage VREF of the output signal VOUT is applied to the non-inverting input terminal 262b of the operational amplifier 262 and to the other end of the resistance element 272 on an opposite side of the one end to which the switch SW2b is coupled.

In addition, in the first embodiment, the output signal VOUT is also input to the comparator 330 as a signal for the threshold judgment. The comparator 330 may be a general window comparator circuit. The comparator 330 is input with VH=VREF+X as a positive side judgment value, and VL=VREF−X as a negative side judgment value.

Although not described in the drawings, the judgment values may be input to the comparator 330 via an attenuator or a filter with a particular band limit. When the attenuator is used, the judgment values VH and VL may be any value. The VH and VL are also input to the adjustment circuit 320. The adjustment circuit 320 divides the +X used in the threshold judgment by G and outputs VHX=VREF+X/G and VLX=VREF−X/G to the selector circuit 340. The comparator 330 inputs the DET signal to the selector circuit 340, the switch SW2a, the switch SW2b, and the switch SW2c.

When VL<VOUT<VH, the DET signal is Lo, and the switch SW2a, the switch SW2b, and the switch SW2c are in the OFF state.

When VH<VOUT or VL>VOUT, the DET signal is Hi, and the switch SW2a, the switch SW2b, and the switch SW2c are in the ON state. In addition, the DET_POL signal that is the output of the comparator 330 is input to the selector circuit 340.

When VH<VOUT, the DET_POL signal is Hi, and when VL>VOUT, the DET_POL signal is Lo. When a combined determination of the DET_POL signal and the DET signal exceeds the threshold VH of the positive side, the selector circuit 340 outputs the first offset signal VHX as the offset signal VS. On the other hand, when the combined determination falls below the threshold VL of the negative side, the selector circuit 340 outputs the second offset signal VLX as the offset signal VS. The offset signal VS is input to the inverting input terminal 262a of the operational amplifier 262 via the resistance element 273 and the switch SW2c.

Although a voltage obtained by adjusting the judgment values VH and VL used for judging the threshold of the comparator 330 is input to the selector circuit 340, a voltage that is correlated with the thresholds VH and VL may be input, a voltage that is not correlated may be input, and may be selected as appropriate.

When the switches SW1a, SW1b are ON and the switches SW2a, SW2b, and SW2c are OFF, the output signal VOUT is expressed by the expression below.

$$VOUT = ( 1 + R 3 / R 1 ) \times VREF - R 3 / R 1 \times VIN \qquad ( 1 )$$

Here, when R2=2× R1 and R3=4× R1, Expression 1 is expressed by the expression below.

$$VOUT = 5 \times VREF - 4 \times VIN \qquad ( 2 )$$

When the switches SW1a, SW1b are ON and the switches SW2a, SW2b, and SW2c are ON, the output signal VOUT is expressed by the expression below.

$$VOUT = ( 1 + R 3 / ( 2 \times R 2 ) + R 3 / ( 2 \times R 1 ) \times VREF - R 3 / ( 2 \times R 1 ) \times VIN - R 3 / ( 2 \times R 2 ) \times VS \qquad ( 3 )$$

Here, when R2=2× R1 and R3=4× R1, Expression 3 is expressed by the expression below.

$$VOUT = 4 \times VREF - 2 \times VIN - VS \qquad ( 4 )$$

From Expressions 2 and 4, when the switches SW2a, SW2b, and SW2c are OFF, a coefficient of the detection signal VIN is −4. On the other hand, when the switches SW2a, SW2b, and SW2c are ON, the coefficient of the detection signal VIN is −2. This corresponds to the output signal VOUT being threshold-judged by the comparator 330 and the switches SW2a, SW2b, and SW2c switching from OFF to ON, causing the amplification factor to decrease from the detection signal VIN to the output signal VOUT.

Here, the offset signal VS for the output signal VOUT to not change at a timing when the switches SW2a, SW2b, and SW2c change from OFF to ON is when the VOUT of the Expression 2 and the VOUT of the Expression 4 represent a same value. That is, it is when Expression 5 below is satisfied.

$$5 \times VREF - 4 \times VIN = 4 \times VREF - 2 \times VIN - VS \qquad ( 5 )$$

From the Expression 5, the offset signal VS for the output signal VOUT to not change is expressed by Expression 6.

$$VS = - VREF + 2 \times VIN \qquad ( 6 )$$

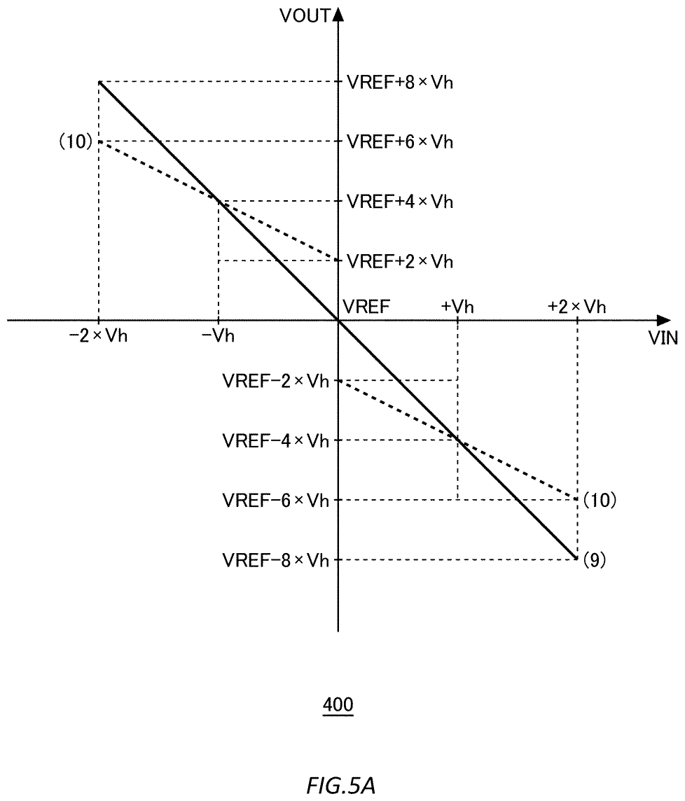

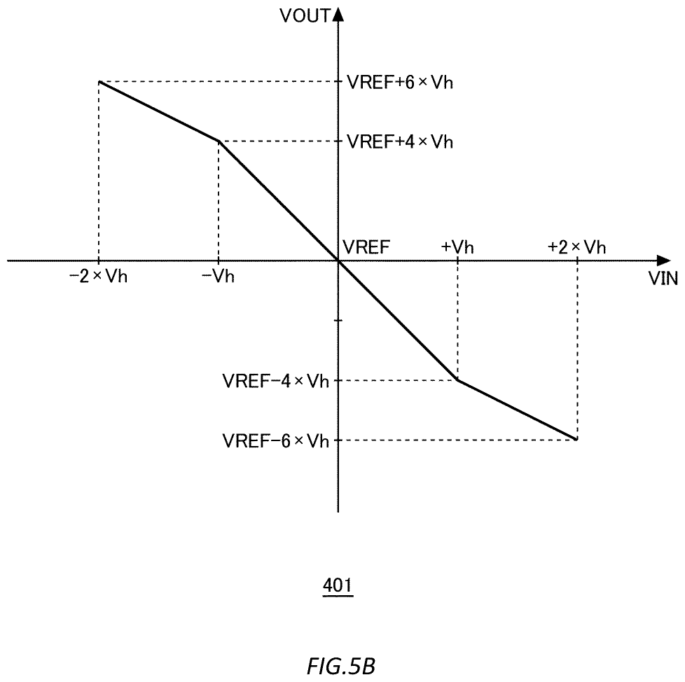

FIG. 5A and FIG. 5B illustrate an example of output characteristics of the output signal VOUT with respect to the detection signal VIN. Here, the output characteristics of the output signal VOUT with Vh being a variable of the measurement current are represented as in the expression below. Here, Vh is a positive real number.

The detection signal VIN is expressed as in the expression below by using an output signal Vh output from the magnetic sensor 220 and the reference voltage VREF.

$$VIN = \pm Vh + VREF \qquad ( 7 )$$

By substituting the Expression 7 in the Expression 6, the offset signal VS is expressed by Expression 8 below.

$$VS = VREF \pm 2 \times Vh \qquad ( 8 )$$

When the switches SW1a and SW1b are ON and the switches SW2a, SW2b, and SW2c are OFF, the output signal VOUT is expressed by the expression below by substituting the Expression 7 in the Expression 2.

$$\begin{matrix}VOUT = 5 \times VREF - 4 \times VIN \\ = VREF - 4 \times ( \pm Vh )\end{matrix} \qquad ( 9 )$$

When the switches SW1a and SW1b are ON and the switches SW2a, SW2b, and SW2c are ON, the output signal VOUT is expressed by the expression below by substituting the Expression 7 and the Expression 8 in the Expression 4. However, VS is an offset voltage (fixed value).

$$\begin{matrix}VOUT = 4 \times VREF - 2 \times VIN - VS \\ = ( VREF - 2 \times ( \pm Vh ) - 2 \times ( \pm Vh )\end{matrix} \qquad ( 10 )$$

The graphs illustrated in FIG. 5A and FIG. 5B are graphs illustrating the output characteristics of the output signal VOUT when an adjustment value G in the adjustment circuit 320 is G=2, VH=VREF+4× Vh, VL=VREF−4×Vh, VHX=VREF+2×Vh, and VLX=VREF−2×Vh.

A graph 400 of FIG. 5A is a composition of individual graphs of the Expression 9 and the Expression 10. A graph 401 of FIG. 5B is a graph illustrating the output characteristics of the output signal VOUT when the switches SW2a, SW2b, and SW2c are changed from ON to OFF when the output signal VOUT does not fall within the predetermined amplitude range W from VREF−4×Vh to VREF+4×Vh.

As above, according to the current sensor 200 of the circuit configuration illustrated in FIG. 3, when the output signal VOUT does not fall within the predetermined amplitude range W, the amplification factor from the detection signal VIN to the output signal VOUT can be changed so as to decrease. In addition, while maintaining accuracy in a range|±Vh|>VIN where the measurement current is a relatively small, output voltage can be suppressed in |±Vh|<VIN, making it possible to obtain a wide range.

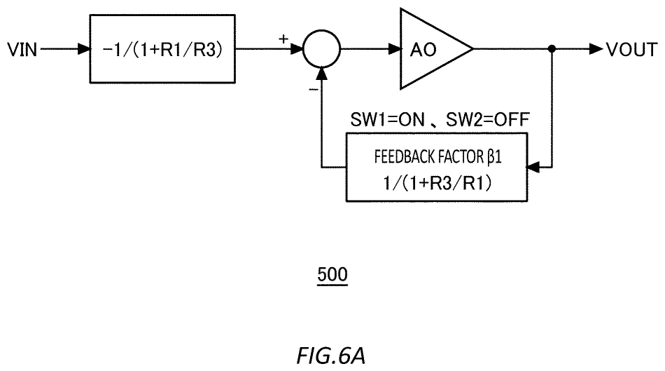

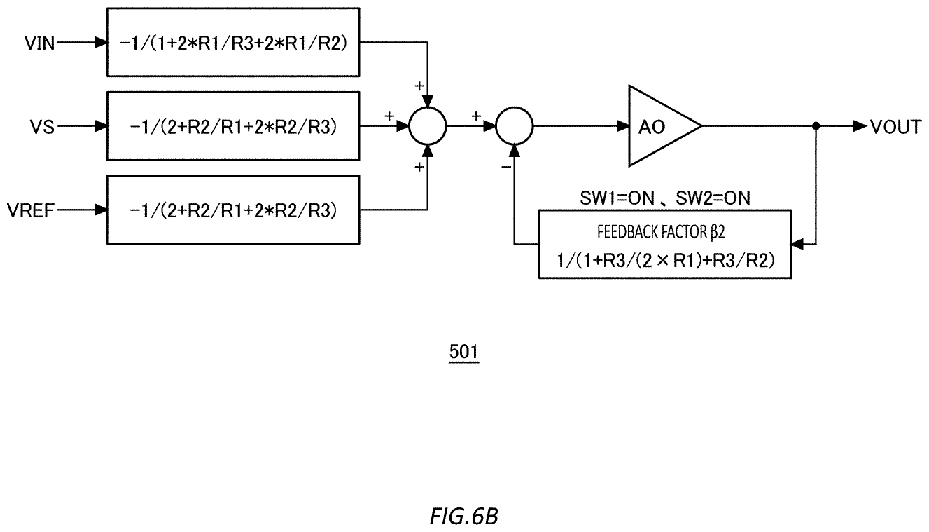

Here, the feedback factor β that is a negative feedback loop of the amplification circuit 260 will be considered. FIG. 6A and FIG. 6B are block diagrams of the operational amplifier 262 of FIG. 3.

When the switches SW1a and SW1b are ON and the switches SW2a, SW2b, and SW2c are OFF, a current input to the inverting input terminal 262a as a voltage VA of the inverting input terminal 262a, when viewed from an input side, can be expressed as (VIN−VA)/R1, and when viewed from an output side, can be expressed as (VA−VOUT)/R3. Since (VIN−VA)/R1 and (VA−VOUT)/R3 have the same value, the expression below is satisfied.

$$( VIN - VA ) / R 1 and ( VREF - VA ) / R 3 \qquad ( 11 )$$

When the Expression 11 is expanded by VA, VA can be expressed by Expression 12 below.

$$VA = ( R 1 / ( R 1 + R 3 ) \times VOUT + ( R 3 / ( R 1 + R 3 ) ) \times VIN \qquad ( 12 )$$

Therefore, when the switches SW1a and SW1b are ON and the switches SW2a, SW2b, and SW2c are OFF, it can be expressed by the block diagram illustrated in FIG. 6A, and a feedback factor β1 can be expressed by Expression 13 below.

$$β 1 = 1 / ( 1 + R 3 / R 1 ) \qquad ( 13 )$$

On the other hand, when the switches SW1a and SW1b are ON and the switches SW2a, SW2b, and SW2c are ON, the current input to the inverting input terminal 262a, when viewed from the input side, can be expressed as (VIN−VA)/R1+ (VREF−VA)/R2+ (VS−VA)/R2, and when viewed from the output side, can be expressed as (VA−VOUT)/(R3/2).

Since (VIN−VA)/R1+ (VREF−VA)/R2+ (VS−VA)/R2 and (VREF−VOUT)/(R3/2) have the same value, Expression 14 below is satisfied.

$$( VIN - VA ) / R 1 + ( VREF - VA ) / R 2 + ( VS - VA ) / R 2 = ( VA - VOUT ) / ( R 3 / 2 ) \qquad ( 14 )$$

By expanding the Expression 14 by VA, VA can be expressed by Expression 15 below.

$$VA = VOUT / ( 1 + R 3 / ( 2 \times R 1 ) + R 3 / R 2 ) + VIN / ( 1 + 2 \times R 1 / R 3 + 2 \times R 1 / R 2 ) + VREF / ( 2 + R 2 / R 1 + 2 \times R 2 / R 3 ) + VS / ( 2 + R 2 / R 1 + 2 \times R 2 / R 3 ) \qquad ( 15 )$$

Therefore, when the switches SW1a and SW1b are ON and the switches SW2a, SW2b, and SW2c are ON, it can be expressed by the block diagram illustrated in FIG. 6B, and a feedback factor β2 can be expressed by Expression 16 below.

$$β 2 = 1 / ( 1 + R 3 / ( 2 \times R 1 ) + R 3 / R 2 ) \qquad ( 16 )$$

Here, since R2=2× R1 and R3=4× R1, 31=β2=1/5 are equal.

That is, according to the configuration of the current sensor 200 illustrated in FIG. 3, variations in the feedback factor of the amplification circuit 260 at the timing when the amplification factor is switched can be suppressed.

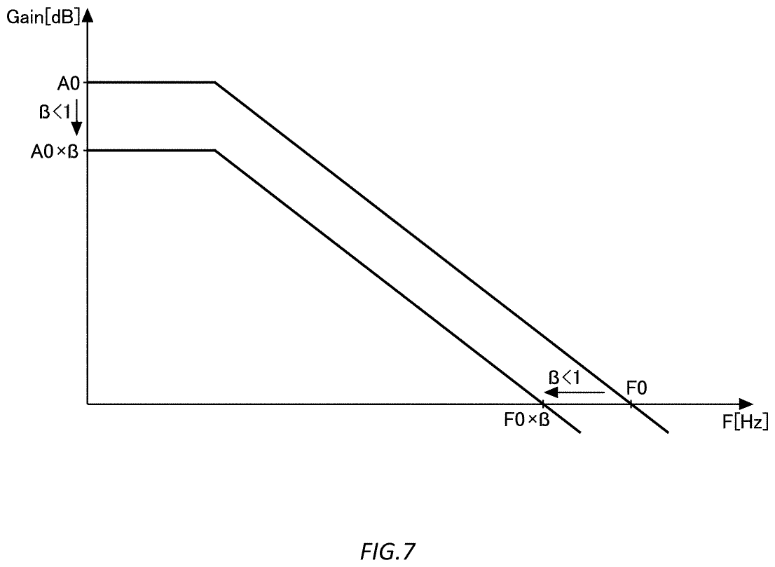

FIG. 7 is an example of a Bode plot illustrating a relationship between F0 and the feedback factor β when the operational amplifier 262 of FIG. 3 has a finite amplification factor A0 and characteristics of a first order LPF.

Generally, when an input signal is amplified by using the operational amplifier 262, the feedback factor β<1. Since an open loop gain configured by a feedback loop is A0× β, it can be seen that gain is smaller, F0 is also smaller, and frequency response is lower than before the feedback loop is configured.

According to the configuration of the current sensor 200 illustrated in FIG. 3, when R2=2×R1 and R3=4×R1, the feedback factor β1=β2 regardless of the ON OFF state of the switches SW2a, SW2b, and SW2c. That is, this means that the open loop gain does not change, and it can be seen that the frequency response also does not change. By the above-described circuit configuration and performing of constant selection, it is possible to control the feedback factor β to not change when the amplification factor from the detection signal VIN to the output signal VOUT is changed to decrease. Although the feedback factor β becomes β1<β2<1 when the amplification factor is simply lowered when |±Vh|<VIN, if a rate of change of the feedback factor is high in a state transition from β1 to β2, performing a transient current response from a small current to a large current causes distortion, so it is better for the rate of change of the feedback factor to be small.

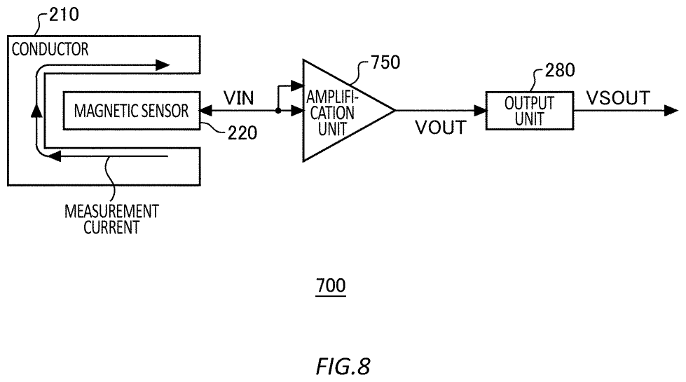

FIG. 8 illustrates an example of a circuit configuration of a current sensor 700 according to a second embodiment. The current sensor 700 detects a measurement current flowing through the conductor 210, similarly to FIG. 2. The current sensor 700 of FIG. 8 and the current sensor 200 of FIG. 2 have similar functions, so only different functions will be described.

An amplification unit 750 is coupled to the output unit 280, and as an example, may be configured as an inverting amplification circuit or a non-inverting amplification circuit using an operational amplifier. The amplification unit 750 may amplify amplitude of a signal by a predetermined gain and output it. The amplification unit 750 is coupled to a branched output of the magnetic sensor 220 as the detection signal VIN, judges an input result based on a predetermined threshold, and controls gain so that it is smaller than a predetermined gain. In addition, similarly to the current sensor 200 according to the first embodiment, a plurality of thresholds may be prepared.

Unlike the current sensor 200, the current sensor 700 performs judgment of the threshold with the detection signal VIN and is suitable for applications that detect transient high currents more quickly.

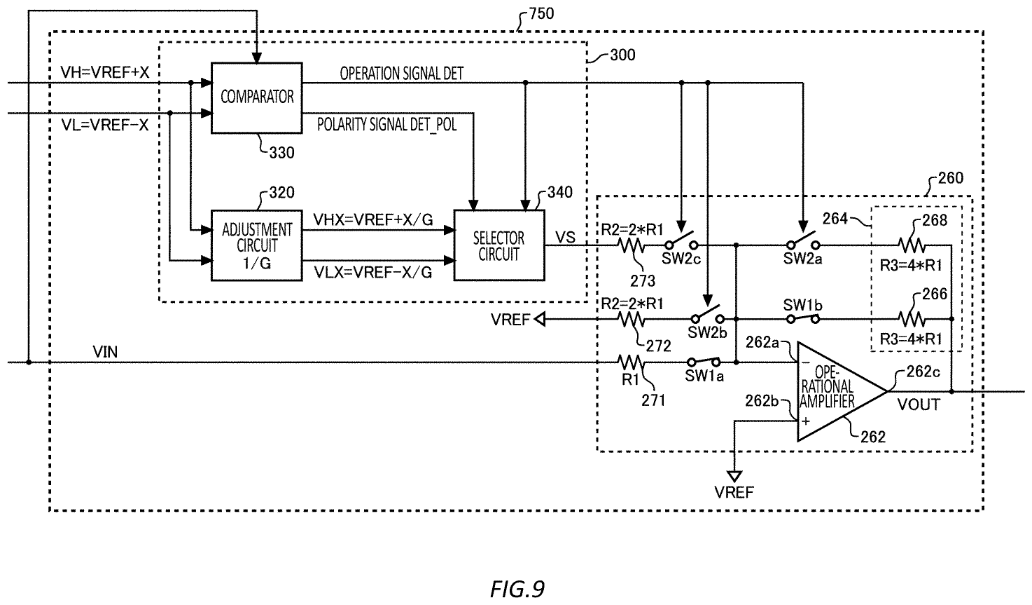

FIG. 9 illustrates an example of a circuit configuration of the amplification unit 750 when an inverting amplification circuit is used. The amplification unit 750 and the amplification unit 250 of FIG. 3 have similar functions, so only different functions will be described. In the amplification unit 750, instead of the output signal VOUT, the detection signal VIN is input as an input signal of the comparator 330. Similarly, the comparator 330 may use a configuration of a general window comparator circuit, and VH=VREF+X is input as a positive side judgment value and VL=VREF−X is input as a negative side judgment value. When the adjustment value G of the adjustment circuit 320 is G=0.5, VH=VREF+Vh, VL=VREF−Vh, VHX=VREF+2×Vh, and VLX=VREF−2×Vh are possible, and the output characteristics of the detection signal VIN to the output signal VOUT are the same as in FIG. 5A and FIG. 5B.

As above, according to the current sensor 200 according to the first embodiment and the current sensor 700 according to the second embodiment, measurable current range can be expanded while suppressing variations in amplitude of a signal output from an amplification circuit that occur with switching of gain. Such a technical effect can be achieved, for example, as shown in the example described above, by a current sensor including a detection unit that outputs a detection signal corresponding to a magnetic field generated around a conductor by a flow of a measurement current therein (for example, a signal generated due to a Hall element receiving a magnetic field), an amplification circuit that includes a first input terminal (for example, an inverting input terminal of an operational amplifier), a second input terminal (for example, a non-inverting input terminal of an operational amplifier), and an output terminal, and amplifies the detection signal input via this first input terminal and outputs an output signal via the output terminal (for example, an operational amplifier or a comparator), where the amplification circuit is configured to be capable of switching at least a first amplification factor and a second amplification factor that is lower than the first amplification factor, and a control circuit that is capable of inputting an offset signal (VS) to the first input terminal (for example, the control circuit 300 in the example), and the control circuit is configured to turn off the input of the offset signal to the first input terminal during a first activation period in which the first amplification factor is set, and turn on the input of the offset signal to the first input terminal during a second activation period in which the second amplification factor is set.

For example, turning on and off the input of the offset signal to this first input terminal is controlled by a switch provided between the control circuit and the amplification circuit described in the example. Then, when an amplitude of the detection signal or the output signal falls within a predetermined amplitude range, an amplification factor of the amplification circuit is set to the first amplification factor (high gain), and when the amplitude of the detection signal or the output signal does not fall within the predetermined amplitude range, the amplification factor of the amplification circuit is set to the second amplification factor (low gain), and thus the input of the offset signal to the first input terminal suppresses change in the amplitude of the output signal that occurs in response to switching the amplification factor of the amplification circuit between the first amplification factor and the second amplification factor.

Further, since a feedback factor of the amplification circuit does not vary with switching of gain, variations in frequency response of the amplification circuit can also be suppressed. Such a technical effect can be achieved, for example, by the amplification circuit as shown by the example described above including an impedance element of which one end is coupled to the first input terminal, and this impedance element functions for suppressing change in a feedback factor of the amplification circuit that occurs by adding the offset signal to the detection signal. It is noted that a typical example of such an impedance element is coupling the resistance element 272 as described above in the example.

It is noted that a resistance value of each resistance element 266, 268, 271, 272, and 273 and a voltage applied to the resistance element 272 described above are an example. Depending on a value of the resistance value of each resistance element 266, 268, 271, 272, and 273 or a magnitude of the offset signal VS, the voltage applied to the resistance element 272 may be adjusted to any voltage based on the reference voltage VREF so that the feedback factor of the amplification circuit 260 does not vary with switching of gain.

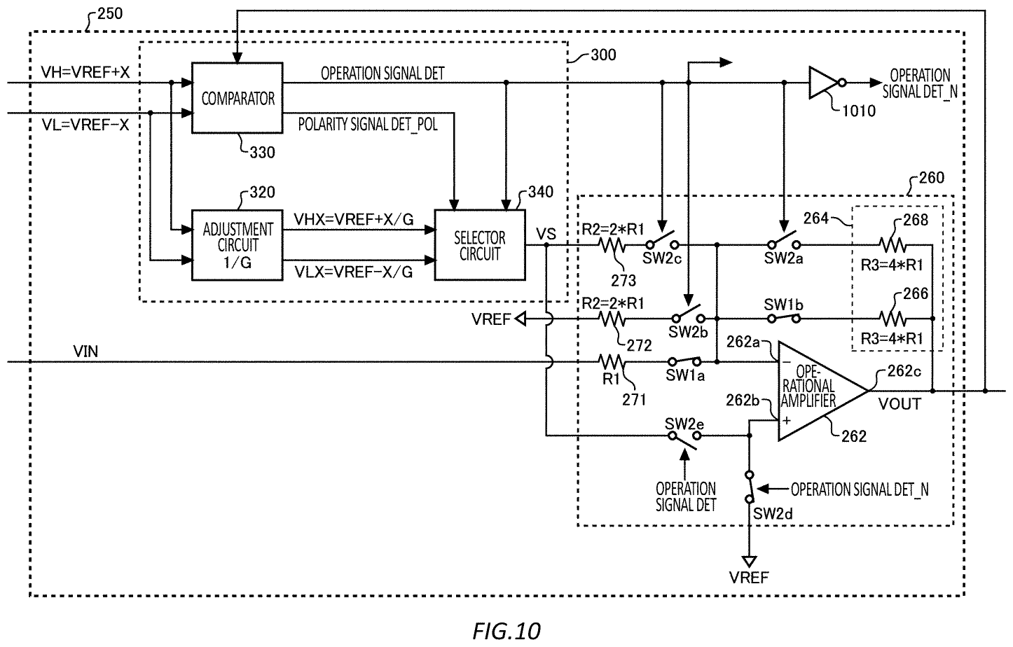

In addition, a further variant of the current sensor described above is illustrated in FIG. 10. FIG. 10 illustrates another example of the circuit configuration using the inverting amplification circuit of the amplification unit 250 according to the first embodiment. It has similar functions, so only differences from the example described above will be described. The operation signal DET that is the output of the comparator 330 is coupled to an INV1010 and outputs an operation signal DET_N that is an inversion of the operation signal DET. A switch SW2d is coupled between the non-inverting input terminal 262b that is the second input terminal of the operational amplifier 262 and VREF, and the switch SW2d is controlled by the operation signal DET_N. An initial state of the switch SW2d (here, the operation signal DET_N is Hi) is ON. A switch SW2e is coupled between the non-inverting input terminal 262b and the offset signal VS that is the output of the selector circuit 340, the SW2e is controlled by the operation signal DET, and its initial state (here, the operation signal DET is Lo) is OFF. When the amplitude of the output signal VOUT does not fall within the predetermined amplitude range W, the switch SW2d is OFF (the operation signal DET_N is Lo) and the switch SW2e is ON (here, the operation signal DET is Hi), and the non-inverting input terminal 262b is coupled from the VREF to the offset signal VS.

Here, since the non-inverting input terminal 262b is coupled from the VREF to the offset signal VS, the detection signal VIN switches from a sum of the output signal Vh output from the magnetic sensor 220 and the reference voltage VREF to a sum of the output signal Vh and the offset signal VS. When the detection signal VIN after this switch is a detection signal VIN′, the detection signal VIN′ is expressed by the expression below.

$${VIN}^{′} = \pm Vh + VS \qquad ( 17 )$$

Then, in a state where the non-inverting input terminal 262b is coupled from the VREF to the offset signal VS, the switches SW1a and SW1b are ON, the switches SW2a, SW2b, SW2c, and SW2e are ON, and the switch SW2d is OFF, and the output signal VOUT is expressed by the expression below.

$$VOUT = ( 1 + R 3 / ( 2 \times R 2 ) + R 3 / ( 2 \times R 1 ) ) \times VS - R 3 / ( 2 \times R 1 ) \times {VIN}^{′} - R 3 / ( 2 \times R 2 ) \times VREF \qquad ( 18 )$$

Here, when resistance elements are coupled so that R2=2×R1 and R3=4×R1, the Expression 18 is expressed by the expression below.

$$VOUT = 4 \times VS - 2 \times {VIN}^{′} - VREF \qquad ( 19 )$$

Here, at a timing when the switches SW2a, SW2b, SW2c, and SW2e are changed from OFF to ON and the switch SW2d is changed from ON to OFF (that is, a timing when gain of the amplification circuit 260 switches), variations in the output signal VOUT can be suppressed by setting the offset signal VS so that the VOUT in the Expression 2 and the VOUT in the Expression 19 represent a same value. That is, the offset signal VS is controlled to satisfy Expression 20 below.

$$5 \times VREF - 4 \times VIN = 4 \times VS - 2 \times {VIN}^{′} - VREF \qquad ( 20 )$$

By substituting the Expression 7 and the Expression 17 in the Expression 20, the offset signal VS is expressed by Expression 21 below.

$$VS = VREF - ( \pm Vh ) \qquad ( 21 )$$

Further, by substituting the Expression 17 and the Expression 21 in the Expression 19, the output signal VOUT is expressed by Expression 22 below. It is noted that expression VS is an offset signal and is a fixed value.

$$VOUT = ( VREF - 2 \times ( \pm Vh ) ) - 2 \times ( \pm Vh ) \qquad ( 22 )$$

Here, it can be seen that the Expression 10 and the Expression 22 are the same expression. Thus, although FIG. 10 is a different coupling method from FIG. 3, since the same result can be obtained, the output characteristics of the output signal VOUT with respect to the detection signal VIN illustrated in FIG. 5A and FIG. 5B are also the same.

However, when deriving the input and output graphs illustrated in FIG. 5A and FIG. 5B based on the embodiment illustrated in FIG. 10, the output characteristics of the output signal VOUT are illustrated when the adjustment value G of the adjustment circuit 320 is G=4, VH=VREF+4×Vh, VL=VREF−4×Vh, VHX=VREF+Vh, and VLX=VREF−Vh.

While the present invention has been described above by using the embodiments, the technical scope of the present invention is not limited to the scope of the above-described embodiments. It is apparent to persons skilled in the art that various alterations or improvements can be made to the above-described embodiments. It is also apparent from description of the claims that the embodiments to which such modifications or improvements are made may be included in the technical scope of the present invention.

It should be noted that each process of the operations, procedures, steps, stages, and the like performed by the apparatus, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

### EXPLANATION OF REFERENCES

100: current sensor;
110a: current path;
120a, 120b: magnetic sensor;
130: receiving unit;
140: filter unit;
150a, 150b: amplification unit;
160: output unit;
170: chopper circuit;
180: correction unit;
200, 700: current sensor;
210: conductor;
220: magnetic sensor;
250, 750: amplification unit;
260: amplification circuit;
262: operational amplifier;
262a: inverting input terminal;
262b: non-inverting input terminal;
262c: output terminal;
264: feedback resistance circuit;
266, 268, 271, 272, 273: resistance element;
280: output unit;
290: correction unit;
300: control circuit;
SW1a, SW1b, SW2a, SW2b, SW2c: switch;
320: adjustment circuit;
330: comparator;
340: selector circuit;
DET: operation signal;
DET_POL: polarity signal;
VIN: detection signal;
VOUT: output signal;
G: adjustment value;
HL: threshold signal (lower limit value);
HV: threshold signal (upper limit value);
VS, VHX, VLX: offset signal;
VREF: reference voltage.

What is claimed is:

1. A current sensor comprising:
a detection unit which outputs a detection signal corresponding to a magnetic field generated around a conductor by a flow of a measurement current therein;
an amplification circuit, including a first input terminal, a second input terminal, and an output terminal, which amplifies the detection signal input via the first input terminal and outputs an output signal via the output terminal; and
a control circuit which is capable of inputting an offset signal to the first input terminal, wherein
the amplification circuit is configured to be capable of switching at least a first amplification factor and a second amplification factor that is lower than the first amplification factor, and
the control circuit is configured to turn off the input of the offset signal to the first input terminal during a first activation period in which the first amplification factor is set, and turn on the input of the offset signal to the first input terminal during a second activation period in which the second amplification factor is set.

2. The current sensor according to claim 1, wherein the control circuit
when an amplitude of the detection signal or the output signal falls within a predetermined amplitude range, sets an amplification factor of the amplification circuit to the first amplification factor, and when the amplitude of the detection signal or the output signal does not fall within the predetermined amplitude range, sets the amplification factor of the amplification circuit to the second amplification factor, and
inputs of the offset signal to the first input terminal suppresses change in the amplitude of the output signal that occurs in response to switching the amplification factor of the amplification circuit between the first amplification factor and the second amplification factor.

3. The current sensor according to claim 2, wherein
the amplification circuit includes an impedance element of which one end is coupled to the first input terminal, and
the impedance element functions for suppressing change in a feedback factor of the amplification circuit that occurs by adding the offset signal to the detection signal.

4. The current sensor according to claim 3, wherein
a reference voltage is applied to the second input terminal, and a voltage based on the reference voltage is applied to another end of the impedance element.

5. The current sensor according to claim 2, wherein
the amplification circuit includes a feedback resistance circuit that is coupled between the output terminal and the first input terminal and set to a first resistance value in a case of the first amplification factor, and set to a second resistance value lower than the first resistance value in a case of the second amplification factor, and
the control circuit sets a resistance value of the feedback resistance circuit to the first resistance value when the amplitude of the detection signal or the output signal falls within the predetermined amplitude range, and sets the resistance value of the feedback resistance circuit to the second resistance value when the amplitude of the detection signal or the output signal does not fall within the predetermined amplitude range.

6. The current sensor according to claim 5, wherein,
the feedback resistance circuit includes
a first resistance element coupled between the output terminal and the first input terminal, and
a second resistance element coupled in parallel with the first resistance element between the output terminal and the first input terminal, and
the control circuit
controls the feedback resistance circuit so that the first resistance element is electrically coupled between the output terminal and the first input terminal and the second resistance element is not electrically coupled between the output terminal and the first input terminal when the amplitude of the detection signal or the output signal falls within the predetermined amplitude range, and
controls the feedback resistance circuit so that the first resistance element and the second resistance element are electrically coupled between the output terminal and the first input terminal when the amplitude of the detection signal or the output signal does not fall within the predetermined amplitude range.

7. The current sensor according to claim 2, wherein the control circuit
adds a first offset signal of a first voltage to the detection signal as the offset signal when the amplitude of the detection signal or the output signal exceeds an upper limit value of the predetermined amplitude range, and
adds a second offset signal of a second voltage lower than the first voltage to the detection signal as the offset signal when the amplitude of the detection signal or the output signal falls below a lower limit value of the predetermined amplitude range.

8. The current sensor according to claim 6, wherein
the amplification circuit includes
a third resistance element having one end to which the detection signal is input and another end coupled to the first input terminal,
a fourth resistance element having one end to which a reference voltage is applied and another end coupled to the first input terminal,
a fifth resistance element having one end to which the offset signal is input and another end coupled to the first input terminal,
a first switch which switches whether the second resistance element is electrically coupled between the output terminal and the first input terminal,
a second switch which switches whether the fourth resistance element is electrically coupled to the first input terminal, and
a third switch which switches whether the fifth resistance element is electrically coupled to the first input terminal, and
the control circuit includes
a comparator which, when the amplitude of the detection signal or the output signal does not fall within the predetermined amplitude range, outputs an operation signal for operating the first switch, the second switch, and the third switch, electrically coupling the second resistance element between the output terminal and the first input terminal, electrically coupling the fourth resistance element to the first input terminal, and electrically coupling the fifth resistance element to the first input terminal, and a polarity signal representing whether the amplitude of the detection signal or the output signal exceeds an upper limit value of the predetermined amplitude range or falls below a lower limit value of the predetermined amplitude range, and
a selector circuit which, based on the operation signal and the polarity signal, inputs a first offset signal of a first voltage as the offset signal to the one end of the fifth resistance element when the amplitude of the detection signal or the output signal exceeds the upper limit value of the predetermined amplitude range, and inputs a second offset signal of a second voltage lower than the first voltage as the offset signal to the one end of the fifth resistance element when the amplitude of the detection signal or the output signal falls below the lower limit value of the predetermined amplitude range.

9. The current sensor according to claim 8, wherein
the comparator controls the output of the operation signal and the polarity signal by comparing, with the detection signal or the output signal, a first threshold signal of a third voltage representing the upper limit value of the predetermined amplitude range obtained by adding a threshold voltage to the reference voltage, and a second threshold signal of a fourth voltage representing the lower limit value of the predetermined amplitude range obtained by subtracting the threshold voltage from the reference voltage, and
the control circuit further includes an adjustment circuit which inputs, to the selector circuit, the first offset signal of the first voltage obtained by adding an adjustment voltage based on the threshold voltage to the reference voltage, and the second offset signal of the second voltage obtained by subtracting the adjustment voltage from the reference voltage.

10. The current sensor according to claim 8, wherein
a resistance value of the fourth resistance element and the fifth resistance element is double a resistance value of the third resistance element, and
a resistance value of the first resistance element and the second resistance element is four times the resistance value of the third resistance element.

11. The current sensor according to claim 2, wherein
the detection unit includes at least one magnetic sensor.

12. The current sensor according to claim 11, wherein
the at least one magnetic sensor is a Hall element, a magneto-resistance element (MR), a giant magneto-resistance element (GMR), a tunneling magneto-resistance element (TMR), a magnetic impedance element (MI element), or an inductance sensor.

13. A current sensor comprising:
a detection unit which outputs a detection signal corresponding to a magnetic field generated around a conductor by a flow of a measurement current therein;
an amplification circuit, including a first input terminal, a second input terminal, and an output terminal, which amplifies the detection signal input via the first input terminal and outputs an output signal via the output terminal; and
a control circuit which is capable of inputting an offset signal to the first input terminal and the second input terminal, wherein
the amplification circuit is configured to be capable of switching at least a first amplification factor and a second amplification factor that is lower than the first amplification factor, and
the control circuit is configured to turn on the input of the offset signal to the first input terminal during a second activation period in which the second amplification factor is set, and turn off the input of the offset signal to the first input terminal during a first activation period in which the first amplification factor is set.
